(19) United States
(12) Patent Application Publication
(10) Pub. No.: US 2026/0231369 A1
(43) Pub. Date: Aug. 6, 2026

(54) COOLING SYSTEM FOR THE LIQUID IMMERSION COOLING OF ELECTRONIC COMPONENTS

(71) Applicant: Wieland-Werke AG, Ulm (DE)

(72) Inventors: Achim GOTTERBARM, Dornstadt (DE); Michael SCHEUSS, Köln (DE); Harald GAIBLER, Rottenacker (DE); Verena OBST, Neu-Ulm (DE); Philipp HOFMANN, Weissenhorn (DE)

(21) Appl. No.: 19/149,581

(22) PCT Filed: Jan. 23, 2024
(86) PCT No.: PCT/EP2024/051465

§ 371 Date: Jul. 21, 2025

(30) Foreign Application Priority Data
Feb. 3, 2023 (DE) 10 2023 000 335.2

(51) Int. Cl. H05K 7/20

(52) U.S. Cl. CPC H05K 7/20327; H05K 7/203

(57) ABSTRACT

A cooling system including liquid immersion cooling of electronic components, a container which can be filled with a two-phase heat transfer fluid and into which electronic components can be immersed in the liquid phase thereof. The container has a gas chamber over the surface of the liquid heat transfer fluid and a lid for closing the container in a fluid-tight manner. The lid or the container has a seal device, having a side which faces the gas chamber, a side which faces away from the gas chamber, and a seal which prevents the passage of a gaseous fluid and which has a seal surface. Furthermore, at least the side facing the gas chamber is configured to be continuous as a vapor barrier against the chemical effect of the fluid.

The invention relates to a cooling system for the liquid immersion cooling of electronic components in accordance with the preamble of claim 1.

Depending on the application in operation, conventional electronic components are designed for a certain temperature range, with an upper temperature limit which must not be exceeded. These components therefore possibly have to be cooled, in order that their internal temperature remains below the predefined upper limits. The cooling can take place, inter alia, by the evaporation of a dielectric heat transfer fluid such as, for example, perfluorohydrocarbons, fluorinated hydrocarbons, fluoroketones or fluorinated hydrocarbon ethers. Depending on the composition, the dielectric heat transfer fluid can have a boiling point in the range from approximately 35° C. to approximately 100° C. at atmospheric pressure. In this temperature range, the boiling point of the heat transfer fluid at atmospheric pressure is lower than the permissible upper limits, for which conventional electronic components are designed. The electronic components are immersed into the liquid phase of the heat transfer fluid. If the surfaces of the electronic components which are in contact with the dielectric heat transfer fluid reach the boiling point of the heat transfer fluid, the liquid fluid located in the vicinity evaporates and thus absorbs the excess heat of the electronic components.

Document DE 35 22 798 A1 has disclosed a cooling apparatus for electronic components which are immersed into a liquid. A liquid container which is open at the top is closed by a lid. To this end, the upper edge of the container is configured as a flange, on which a simple seal is placed onto the planar flange surface and is closed by way of the lid. The container flange is connected fixedly to the lid by means of screws.

Furthermore, document US 2019/0 357 379 A1 describes a two-phase immersion cooling apparatus for electronic components. In order to minimize the losses of the dielectric during the use of this two-phase system, the cooling container is provided with a clearance which has an excess height above the condenser device, with the result that only a small proportion of vapor of the heat transfer fluid reaches the upper side of the metal tank.

Moreover, the upper side of the metal tank is covered by a lid or an accessory plate made from metal or glass. The gap between the container and the lid is sealed here by O-rings or other seals made from elastomers. Although a large part of the dielectric in the vapor phase condenses on the condenser device, a certain gas proportion in practice passes as far as the lid and penetrates there into the gap between the lid and the container as far as the seal. Dielectric fluids have the chemical property of attacking and damaging some seal materials, with the result that the sealing function cannot be ensured reliably in the long term.

The invention is based on the object of developing a cooling system for the liquid immersion cooling of electronic components.

The invention is described by the features of claim 1. The further dependent claims relate to advantageous embodiments and developments of the invention.

The invention includes a cooling system for the liquid immersion cooling of electronic components, comprising: a container, the interior of which can be filled with two-phase heat transfer fluid, into the liquid phase of which electronic components can be immersed, wherein the container has a gas chamber above the surface of the liquid heat transfer fluid, and a lid for closing the container in a fluid-tight manner.

The lid or the container has a sealing device, with a side which faces the gas chamber and a side which is averted from the gas chamber, and with a seal which has a sealing surface and prevents the passage of gaseous fluid. Furthermore, at least the side which faces the gas chamber is configured as a vapor barrier in a manner which is resistant to the chemical action of the fluid.

Within the context of the present invention, the term “vapor barrier” is used synonymously with the term “moisture barrier”. The effect of the vapor barrier is a barrier which at least inhibits or completely prevents the passage of fluid.

In two-phase system immersion cooling systems, for example, the electronic components are arranged in the vicinity of the bottom of a metal container. The metal tank is filled with a dielectric heat transfer fluid. The liquid phase of the dielectric is in direct thermal contact with the electronic components. During operation, the electronic components generate heat. The heat is dissipated from the components by evaporation of the heat transfer fluid. The dielectric heat transfer fluid has a much lower density in the vapor phase than the heat transfer fluid in the liquid phase, and forms a gas chamber above the surface of the liquid. Condensers as heat exchanger devices, in which water at a temperature of at least 15° C. below the boiling point of the dielectric lies in the liquid phase, are arranged in the gas chamber of the metal tank. The dielectric fluid in the vapor phase flows through the condenser in a general upward direction. Upon contact with the condensers, the dielectric fluid in the vapor phase outputs heat to the condensers and returns in a liquid phase. The dielectric in the liquid phase, the density of which is much higher than that of the dielectric in the vapor phase, flows due to gravity in the direction of the bottom of the metal tank. The cycle consists of the evaporating of the liquid in contact with the electronic components, the rising of the vapor over the liquid, the converting of the vapor in contact with the condensers into liquid, and the liquid which flows back through the vapor. This circuit makes the transmission of the heat generated by the electronic components to the condenser possible.

The invention proceeds here from the observation that the cooling systems for the liquid immersion cooling of electronic components comprise a container which has a lid for closing the container in a fluid-tight manner. In the interior, the cooling system is filled in operation with two-phase heat transfer fluid, into the liquid phase of which electronic components are immersed. The gas phase which emerges from the liquid heat transfer fluid is collected in the container in a gas chamber above the surface of the liquid heat transfer fluid, and penetrates as far as into the remaining gap formed by the lid and the container. There, the lid or the container has a sealing device, with a side which faces the gas chamber and a side which is averted from the gas chamber, and with a sealing surface which prevents the passage of gaseous fluid. Furthermore, at least the side which faces the gas chamber is configured as a vapor barrier in a manner which is resistant to the chemical action of the fluid.

The particular advantage consists in that that side of the sealing device which faces the gas chamber is resistant to chemical influences with respect to the vapor phase of the heat transfer fluid, and does not attack and damage the seal materials which are used there. In practice, the gas proportion which penetrates into the gap between the lid and the container is thus effectively kept away from chemically sensitive seal materials, and the sealing function is ensured reliably in the long term.

In one preferred refinement of the invention, that sealing surface of the seal which prevents the passage of gaseous fluid can be of elastic configuration. Elastic materials such as, for example, thermoplastic elastomers can be configured here in a foam-like manner with a multiplicity of cavities, for example as a sealing strip, or can have geometrically hollow structures, for example hollow profiles. Overall, a substantially hermetic seal is intended to take place at the sealing surface, which seal withstands both a certain positive pressure and a certain negative pressure in the container interior.

The sealing device can advantageously be of single-piece configuration. In a single-piece manner in one component, the functionality of the sealing device can firstly be resistant to the chemical action of the fluid as a vapor barrier on the side which faces the gas chamber. Secondly, a sealing surface which is averted from the gas chamber can completely prevent the passage of gaseous fluid. In addition, a sealing device which runs over the entire sealing surface without interruption can be configured.

In contrast, it is also advantageous that the sealing device can be of multiple-piece configuration with a vapour barrier with a side which faces the gas chamber and a flexible seal which has a sealing surface and is arranged behind the vapor barrier on the side which is averted from the gas chamber, and prevents the passage of fluid. In a configuration of this type of the sealing device, a greater range of materials with different and therefore optimized properties can be used structurally. The multiple-piece sealing device can refer to a peripheral sealing surface in multiple pieces, and to the vapor barriers and seals with sealing surfaces which are arranged behind one another starting from the gas chamber.

In one advantageous embodiment of the invention, that side of the sealing device which faces the gas chamber can comprise metal. Elastic metal seals are particularly preferred here which close the gap effectively with respect to an exchange of gas as a result of spring-elastic properties. Elastic metal seals of this type have the capability of springing back in a defined manner when relieved of load. Therefore, elastic metal seals cause a certain contact pressure at the sealing gap or are configured as a foil which is attached to a carrier material.

In one advantageous refinement of the invention, that side of the sealing device which faces the gas chamber can comprise a foil made from aluminum or an aluminum alloy. In particular, aluminum materials which are connected to a carrier are suitable as foil material.

That material of the seal which configures the sealing surface can advantageously comprise polysiloxane (silicone), fluoroelastomer, polytetrafluoroethylene (PTFE) and/or nitrile rubber (NBR). Important criteria during the selection of suitable sealing materials are their chemical resistance to the chemical influences of the heat transfer fluid. Further criteria are the temperature and ageing resistance.

In one particularly preferred embodiment, the vapor barrier can be configured such that it can be displaced into a groove in the lid or a groove in the container by means of a spring mechanism. As a result of the spring action, the vapor barrier is pressed onto the respective counterpart, and the gap is closed effectively with respect to an exchange of gas. In particular, a penetration of the vapor barrier into a groove boosts the seal effect.

In a further advantageous refinement of the invention, the sealing device can be configured in a strip-like manner from foam material. Foams usually increase the elasticity of the sealing material, as a result of which a uniform sealing function results over the entire contact surface on the lid and container.

The vapor barrier of the sealing device can advantageously be configured as a labyrinth seal. A labyrinth seal increases the sealing area and reduces the gas passage of the heat transfer fluid to a minimum.

Exemplary embodiments of the invention will be explained in greater detail on the basis of the diagrammatic drawings, in which:

FIG. 1 shows a diagrammatic view of a cooling system according to the invention for electronic components,

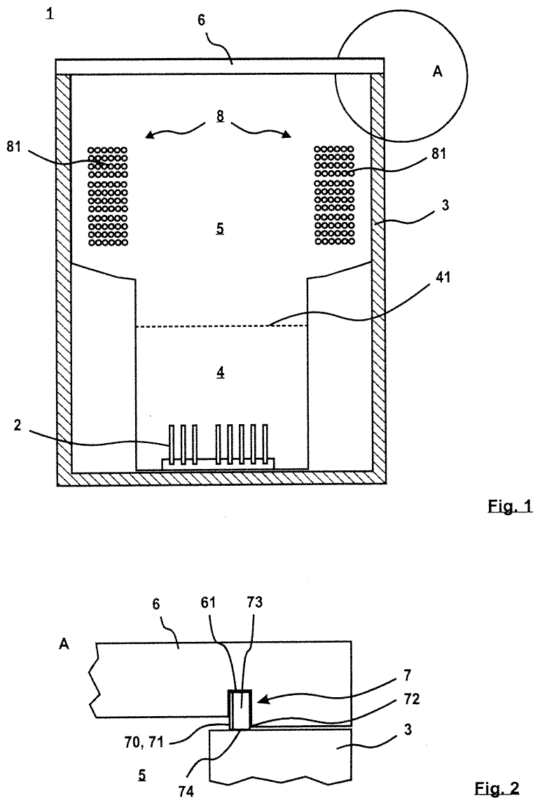

FIG. 2 shows a diagrammatic partial view of the cover and container in the region of a single-piece sealing device,

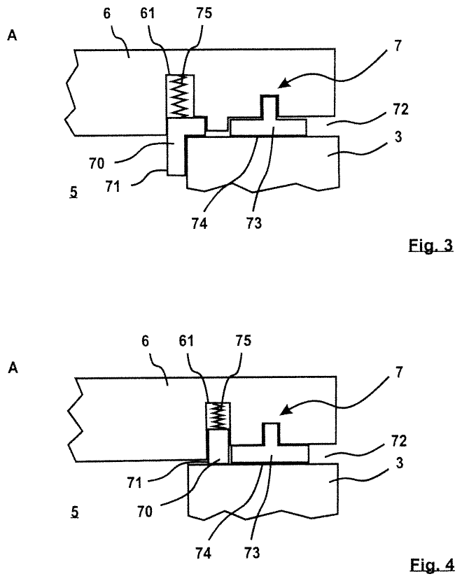

FIG. 3 shows a diagrammatic partial view of the lid and container in the region of a multiple-piece sealing device, and

FIG. 4 shows a diagrammatic partial view of the lid and cover in the region of a further multiple-piece sealing device.

Parts which correspond to one another are provided with the same designations in all the figures.

FIG. 1 shows a diagrammatic view of a cooling system 1 according to the invention for electronic components 2. The cooling system 1 comprises a container 3, the interior of which is filled with heat transfer fluid 4, into the liquid phase of which electronic components 2 are immersed. Its container 3 has a gas chamber 5 above the surface 41 of the liquid heat transfer fluid 4. The container 3 is closed in a fluid-tight manner by a lid 6. On the common contact surface, the lid 6 or the container 3 has a sealing device 7 (shown in an enlarged manner in image detail A in FIG. 2), with a sealing surface which prevents the passage of gaseous fluid.

The evaporated dielectric heat transfer fluid forms a gas chamber 5 above the surface 41 with a gaseous phase, in which a heat exchanger device 8 with tube bundles 81 as condensers is arranged. The tube bundles 81 are flowed through by water at a substantially lower temperature below the boiling point of the dielectric. Upon contact with the condensers of the tube bundles 81, the gaseous fluid outputs condensation heat.

FIG. 2 shows a diagrammatic partial view A of the lid 6 and container 3 from FIG. 1 in the region of a single-piece sealing device 7.

The sealing device 7 is of strip-like configuration and is embedded into a groove 61 in the lid 6. The sealing surface 74 which prevents the passage of gaseous fluid is situated in the container side.

The functionality (as vapor barrier 70 on the side 71 which faces the gas chamber 5) of the single-piece strip as sealing device 7 is resistant to the chemical action of the fluid. The sealing surface 74 which is averted from the gas chamber 5 is protected by the vapor barrier 70 and prevents the passage of the remaining gaseous fluid. As damping barrier 70, a metal strip or a metal foil is arranged on the side 71 which faces the gas chamber 5. Aluminum or an aluminum alloy which can preferably be used as a flexible foil material is particularly suitable as metal. In this way, the sealing device 7 can run over the entire sealing surface 74 between the container 3 in the lid 6 in one piece without interruption. In specific cases, a plurality of part portions which are joined together to form an entire unit can also be suitable for the sealing device 7.

Elastic metal foils as vapor barrier 70 already close the gap effectively with respect to a passage of gas, with the result that only a very small quantity of the gaseous fluid still passes to the sealing surface 74 of the seal 73 situated behind them. The metal foils are attached on a carrier material, directly on the seal 73 in the case of the single-piece embodiment.

The seal 73 of the sealing device 7 can preferably also be configured from foam material in conjunction with an elastically flexible metal foil as vapor barrier 70. Foams usually increase the elasticity of the sealing material, which results in a uniform sealing function over the entire contact surface.

FIG. 3 shows a diagrammatic partial view A of the cover 6 and container 3 from FIG. 1 in the region of a multiple-piece sealing device 7.

The sealing device 7 is of multiple-piece configuration with a vapor barrier 70 with a side 71 which faces the gas chamber and a flexible seal 73 which has a sealing surface 74 and is arranged behind the vapor barrier on the side 72 which is averted from the gas chamber. Starting from the gas chamber 5, a multiple-piece sealing device 7 of this type has vapor barriers 70 and seals 73 with sealing surfaces 74 arranged behind one another and spaced apart from one another. The vapor barrier 70 is embedded into a groove 61 in the lid 6. The seal 73 is likewise fixed in an upwardly projecting manner in a further groove for securing. The sealing surface 74 which prevents the passage of gaseous fluid is situated on the container side.

In this embodiment, the vapor barrier 70 is configured such that it can be displaced into the groove 61 in the lid 6 by means of a spring mechanism 75. By way of the spring action, the vapor barrier 70 is guided in the groove 61 and is pressed onto the respective counterpart, the container 3. The gap is effectively closed with respect to an exchange of gas in the direction of the following seal 73 just by way of this.

In this case, the vapor barrier 70 of the sealing device 7 projects beyond the upper side as far as the side wall of the container 3 and, in this way, forms particularly great paths for a passage of the gaseous fluid. Labyrinth seals of this type therefore increase the sealing area and reduce the gas passage of the heat transfer fluid to the seal 73 to a minimum.

FIG. 4 shows a diagrammatic partial view A of the lid 6 and container 3 from FIG. 1 in the region of a further embodiment of a multiple-piece sealing device 7.

The sealing device 7 is configured with a vapor barrier 70 with a side 71 which faces the gas chamber and a flexible seal 73 which has a sealing surface 74 and is arranged behind the vapor barrier on the side 72 which is averted from the gas chamber. This multiple-piece sealing device 7 once again has, starting from the gas chamber 5, vapor barriers 70 and seals 73 with sealing surfaces 74 arranged behind one another and spaced apart from one another. The vapor barrier 70 is embedded into a groove 61 in the lid 6. The seal 73 is likewise fastened in an upwardly projecting manner in a further groove for securing. The seal 73 which prevents the passage of gaseous fluid and has the sealing surface 74 is situated directly adjacently to the vapor barrier 70 on the container side. As a result, this further preferred embodiment combines the technical embodiments shown and explained in FIG. 2 and FIG. 3 in a simple solution for a multiple-piece sealing device 7.

### LIST OF DESIGNATIONS

1 Cooling system
2 Electronic components
3 Container
31 Groove in the container
4 Heat transfer fluid
41 Surface of the liquid heat transfer fluid
5 Gas chamber
6 Lid
61 Groove in the lid
7 Sealing device
70 Vapor barrier
71 Side of the sealing device which faces the gas chamber
72 Side of the sealing device which is averted from the gas chamber
73 Seal
74 Sealing surface
75 Spring mechanism
8 Heat exchanger device
81 Tube bundle
A Image detail of the sealing region

1. A cooling system for the liquid immersion cooling of electronic components, comprising:
a container having, an interior fillable with two-phase heat transfer fluid, the heat transfer fluid having a liquid phase in which electronic components are immersible, the container having a gas chamber above a surface of the liquid heat transfer fluid; and
a lid for closing the container in a fluid-tight manner,
the lid or the container having a sealing device with a side facing the gas chamber and a side averted from the gas chamber, and with a seal having a sealing surface and preventing passage of gaseous fluid,
at least the side facing the gas chamber being configured as a vapor barrier in a manner resistant to chemical action of the heat transfer fluid.

2. The cooling system as claimed in claim 1, wherein the sealing surface of the seal which prevents the passage of gaseous fluid is of an elastic configuration.

3. The cooling system as claimed in claim 1, wherein the sealing device is of single-piece configuration.

4. The cooling system as claimed in claim 1, wherein the sealing device is of a multiple-piece configuration with a vapor barrier with a side facing the gas chamber and a flexible seal having a sealing surface and arranged behind the vapor barrier on the side averted from the gas chamber to prevent passage of fluid.

5. The cooling system as claimed in claim 1, wherein the side of the sealing device facing the gas chamber comprises metal.

6. The cooling system as claimed in claim 5, wherein the side of the sealing device facing the gas chamber comprises a foil made from aluminum or an aluminum alloy.

7. The cooling system as claimed in claim 1, wherein the sealing surface comprises polysiloxane, fluoroelastomer, polytetrafluoroethylene and/or nitrile rubber.

8. The cooling system as claimed in claim 1, further including a spring mechanism, the vapor barrier being configured for displacement into a groove in the lid or a groove in the container by the spring mechanism.

9. The cooling system as claimed in claim 1, wherein the sealing device is configured in a strip-like manner from foam material.

10. The cooling system as claimed in claim 1, wherein the vapor barrier of the sealing device is configured as a labyrinth seal.
